(19) United States
(12) Patent Application Publication
(10) Pub. No.: US 2022/0359035 A1
(43) Pub. Date: Nov. 10, 2022

(54) INTEGRATED CIRCUIT TEST APPARATUS

(71) Applicant: NANYA TECHNOLOGY CORPORATION, New Taipei City (TW)

(72) Inventors: Chien-Hwa SU, New Taipei City (TW); Yu-Wei TSENG, New Taipei City (TW); Shang-Ju HSU, Taoyuan City (TW)

(21) Appl. No.: 17/316,702

(22) Filed: May 10, 2021

(51) Int. Cl. G11C 29/50

(52) U.S. Cl. CPC G11C 29/50004; G11C 2029/5004

(57) ABSTRACT

A test apparatus configured to test a device under test includes a power supply and a power compensation circuit. The power supply is configured to supply electric power to a power supply terminal of the device under test via a first route or a second route that are connected in parallel. The first route includes a first switch element configured to be controlled according to a first control signal. The power compensation circuit is located on the second route, wherein the power compensation circuit includes a second switch element configured to be controlled according to a second control signal, the power compensation circuit is configured to generate a compensation pulse current when the first switch element is turned off and the second switch element is turned on.

### BACKGROUND

### Field of Disclosure

The present disclosure relates to a test apparatus, and more particularly to an integrated circuit test apparatus.

### Description of Related Art

With today's mobile electronic devices and computer servers that support them handling ever-increasing volumes of data, semiconductor memory manufacturers need a highly capable, cost-efficient means of testing their latest generations of high-speed, high-capacity memory ICs including emerging DDR4-SDRAM and LPDDR4-SDRAM chips.

A power supply circuit configured to supply electric power to such a DUT (Device under test) has a configuration employing a regulator, for example. Ideally, such a power supply circuit is capable of supplying constant electric power regardless of the load current. However, such a power supply circuit has an output impedance that is not negligible. Accordingly, the power supply voltage fluctuates due to fluctuation in the load. Fluctuation in the power supply voltage affects the test margin for the DUT.

### SUMMARY

The present disclosure provides a test apparatus configured to test a device under test to deal with the needs of the prior art problems.

In one or more embodiments, a test apparatus configured to test a device under test includes a power supply and a power compensation circuit. The power supply is configured to supply electric power to a power supply terminal of the device under test via a first route or a second route that are connected in parallel. The first route includes a first switch element configured to be controlled according to a first control signal. The power compensation circuit is located on the second route, wherein the power compensation circuit includes a second switch element configured to be controlled according to a second control signal, the power compensation circuit is configured to generate a compensation pulse current when the first switch element is turned off and the second switch element is turned on.

In one or more embodiments, a test apparatus configured to test a device under test includes a first power supply, a second power supply and a power compensation circuit. The first power supply is configured to supply electric power to a power supply terminal of the device under test via a first route. The second power supply is configured to supply electric power to the power supply terminal of the device under test via a second route. The power compensation circuit is located on the second route, the power compensation circuit includes a switch element configured to be controlled according to a control signal, the power compensation circuit is configured to generate a compensation pulse current when the switch element is turned on and the second power supply is turned on.

In one or more embodiments, the power supply supplies electric power to the power supply terminal of the device under test via the first route when the first switch element is turned on and the second switch element is turned off.

In one or more embodiments, the test apparatus further includes a driver that is assigned to the second switch element.

In one or more embodiments, the device under test includes an integrated circuit device that is packaged after an assembling process.

In one or more embodiments, the device under test includes a memory integrated circuit device that is packaged after an assembling process.

In one or more embodiments, the memory integrated circuit device includes double data rate synchronous dynamic random-access memory.

In one or more embodiments, the memory integrated circuit device includes low power double data rate synchronous dynamic random-access memory.

In one or more embodiments, the first power supply supplies electric power to the power supply terminal of the device under test via the first route when the switch element is turned off.

In one or more embodiments, the first power supply supplies electric power to the power supply terminal of the device under test via the first route when the second power supply is turned off.

In one or more embodiments, the power compensation circuit is configured to compensate a power voltage drop.

In one or more embodiments, the first power supply is configured to be modulated by a software application to compensate a power voltage drop when the power compensation circuit is malfunctioned.

In sum, the test apparatus disclosed herein has an inventive configuration with a switchable power compensation circuit. The switchable power compensation circuit may be implemented with single power supply or two power supplies to meet various testing requirements. The test apparatus can have flexible power supply sources to meet various testing requirements.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 illustrates a configuration of a test apparatus according to one embodiment of the present disclosure;

FIG. 2 illustrates another configuration of a test apparatus according to another embodiment of the present disclosure;

FIG. 3 illustrates another configuration of a test apparatus according to still another embodiment of the present disclosure; and

FIG. 4 is a comparative diagram which showing compensation pulse currents generated by some embodiments of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

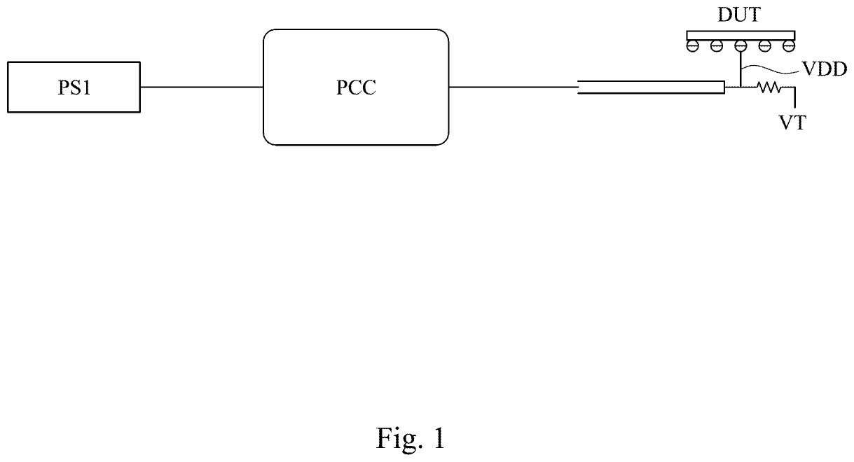

Reference is made to FIG. 1, which illustrates a configuration of a test apparatus according to one embodiment of the present disclosure. FIG. 1 only shows part of the test apparatus (e.g., Advantest memory tester T5503HS with high fidelity tester access fixture design) and a semiconductor integrated circuit device under test DUT. In particular, a power supply PS1 is configured to supply electric power via a route to a power supply terminal Vdd of the semiconductor integrated circuit device under test DUT to execute some testing processes, and a power compensation circuit PCC is designed on this route to compensate a power voltage drop. In some cases, if the power compensation circuit PCC is malfunctioned, this route cannot be utilized to test semiconductor integrated circuit devices. In some embodiments of the present disclosure, the power compensation circuit PCC is a semiconductor integrated circuit.

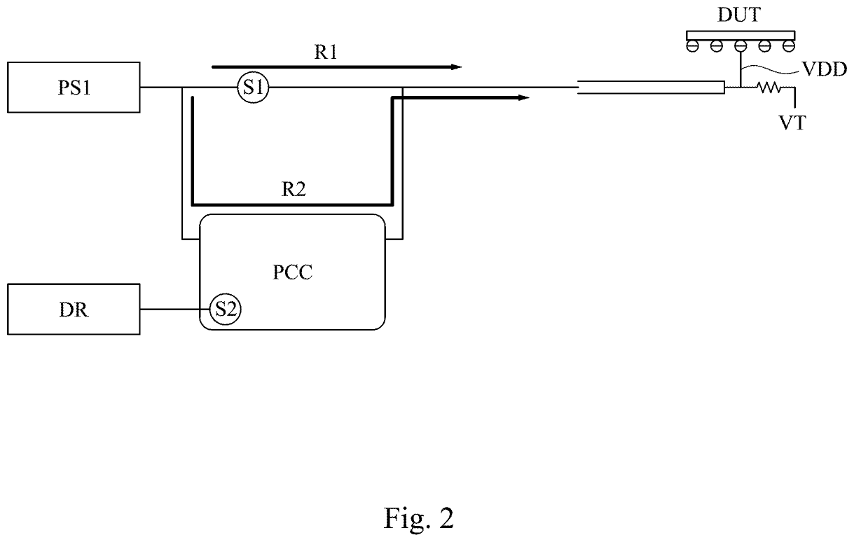

Reference is made to FIG. 2, which illustrates another configuration of a test apparatus according to another embodiment of the present disclosure. In this configuration, a power supply PS1 may supply electric power to a power supply terminal Vdd of the semiconductor integrated circuit device under test DUT via a first route R1 or a second route R2 to execute some testing processes. The first route R1 and the second route R2 are electrically connected in parallel between the power supply PS1 and the power supply terminal Vdd. The first route R1 includes a switch element S1 configured to be controlled according to a control signal, e.g., a control signal provided via a driver. A power compensation circuit PCC is designed on the second route R. The power compensation circuit PCC includes a switch element S2 configured to be controlled according to a control signal, e.g., a control signal provided via a driver DR. The switch element S2 is configured to switch the power compensation circuit PCC between a “turn on” status and a “turn off” status. When the switch element S1 is turned off (the first route R1 is thus broken) and the switch element S2 is turned on (the power compensation circuit PCC is thus turned on), the power supply PS1 is configured to supply electric power to the power supply terminal Vdd of the semiconductor integrated circuit device under test DUT via the second route R2, and the power compensation circuit PCC is configured to generate a compensation pulse current to compensate a power voltage drop for executing some testing processes. In some embodiments of the present disclosure, the power compensation circuit PCC is a semiconductor integrated circuit. When the switch element S1 is turned on and the switch element S2 is turned off (the power compensation circuit PCC is thus turned off), the power supply PS1 supplies electric power to the power supply terminal Vdd of the semiconductor integrated circuit device under test DUT via the first route R1. Since no power compensation circuit is designed on the first route R1, the power supply PS may be further modulated, e.g., by a computer software program, to provide a current similar to the compensation pulse current generated by the power compensation circuit PCC if necessary (e.g., the power compensation circuit PCC on the second route R is malfunctioned). In some embodiments of the present disclosure, some testing processes need power supply PS1 to supply electric power to a power supply terminal Vdd of the semiconductor integrated circuit device under test DUT without power voltage compensation, and the switch element S1 is turned on and the switch element S2 is turned off to achieve that the power supply PS1 supplies electric power to the power supply terminal Vdd of the semiconductor integrated circuit device under test DUT via the first route R1.

In some embodiments of the present disclosure, the device under test DUT may be an integrated circuit device that is packaged after an assembling process. In some embodiments of the present disclosure, the device under test DUT may be a memory integrated circuit device that is packaged after an assembling process. In some embodiments of the present disclosure, the memory integrated circuit device may be a double data rate synchronous dynamic random-access memory device. In some embodiments of the present disclosure, the memory integrated circuit device may be a low power double data rate synchronous dynamic random-access memory device.

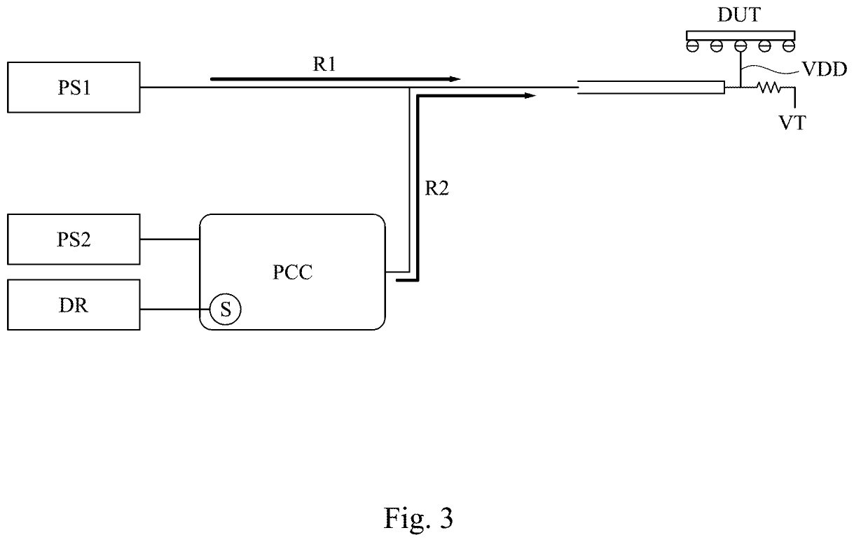

Reference is made to FIG. 3, which illustrates another configuration of a test apparatus according to still another embodiment of the present disclosure. In this configuration, a first power supply PS1 is configured to supply electric power to a power supply terminal Vdd of the device under test DUT via a first route R1, and a second power supply PS2 is configured to supply electric power to the power supply terminal Vdd of the device under test DUT via a second route R2. No power compensation circuit is designed on the first route R1, and a power compensation circuit PCC is designed on the second route R2. The power compensation circuit PCC includes a switch element S configured to be controlled according to a control signal, e.g., a control signal may be provided via a driver DR. The switch element S is configured to switch the power compensation circuit PCC between a “turn on” status and a “turn off” status. In some embodiments of the present disclosure, the power compensation circuit PCC is a semiconductor integrated circuit. When the switch element S is turned on (the power compensation circuit PCC is thus turned on) and the second power supply PS2 is turned on, the second power supply PS2 is configured to supply electric power to the power supply terminal Vdd of the device under test DUT via the second route R2 to execute some testing processes, and the power compensation circuit PCC is configured to generate a compensation pulse current to compensate a power voltage drop. In some embodiments of the present disclosure, some testing processes need power supply to supply electric power to a power supply terminal Vdd of the semiconductor integrated circuit device under test DUT without power voltage compensation, and the first power supply PS1 is thus elected to supply electric power (without power voltage compensation) via the first route R1 to the power supply terminal Vdd of the semiconductor integrated circuit device under test DUT. When the switch element S is turned off (the power compensation circuit PCC is thus turned off) or the second power supply PS2 is turned off, the first power supply PS1 supplies electric power (without power voltage compensation) to the power supply terminal Vdd of the device under test DUT via the first route R1. Since no power compensation circuit is designed on the first route R1, the first power supply PS1 may be further modulated, e.g., by a computer software program, to provide a current similar to the compensation pulse current generated by the power compensation circuit PCC if necessary (e.g., when the power compensation circuit PCC on the second route R is malfunctioned).

In some embodiments of the present disclosure, the device under test DUT may be an integrated circuit device that is packaged after an assembling process. In some embodiments of the present disclosure, the device under test DUT may be a memory integrated circuit device that is packaged after an assembling process. In some embodiments of the present disclosure, the memory integrated circuit device may be a double data rate synchronous dynamic random-access memory device. In some embodiments of the present disclosure, the memory integrated circuit device may be a low power double data rate synchronous dynamic random-access memory device.

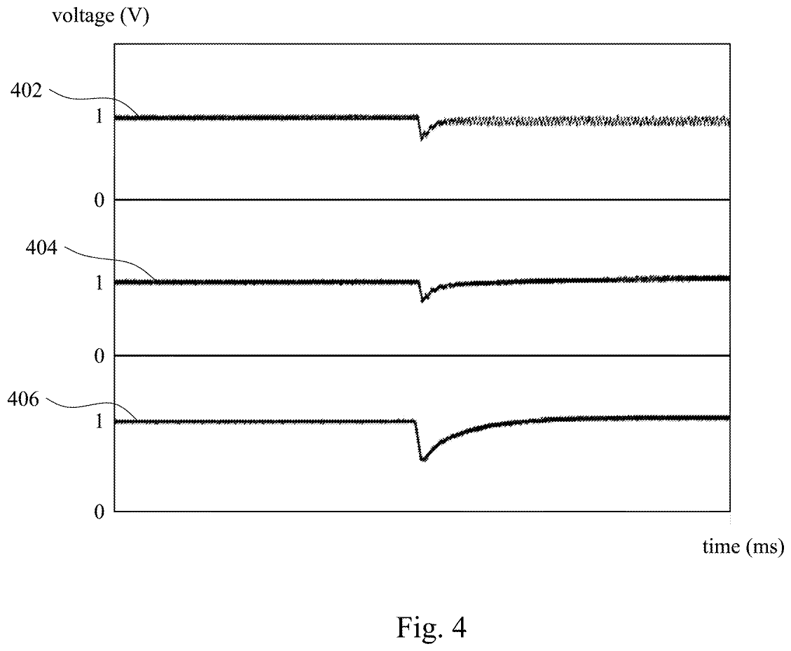

Reference is made to FIG. 4, which is a comparative diagram which showing compensation pulse currents generated by some embodiments of the present disclosure. In this diagram, a voltage curve 402 is measured from the configuration of the test apparatus illustrated in FIG. 1. The power compensation circuit PCC is configured to compensate a power voltage drop shown on the voltage curve 402. Another voltage curve 404 is measured from the configuration of the test apparatus illustrated in FIG. 2 or 3 when the switch element S2 of FIG. 2 is turned on (the switch element S1 is turned off) or the switch element S of FIG. 3 is turned on. The power compensation circuit PCC is configured to compensate a power voltage drop shown on the voltage curve 404 such that the voltage curve 403 is substantially the same as the voltage curve 402. Another voltage curve 406 is measured from the configuration of the test apparatus illustrated in FIG. 2 or 3 when the switch element S2 of FIG. 2 is turned off (the switch element S1 is turned on) or the switch element S of FIG. 3 is turned off, and the first power supply PS1 is further modulated, e.g., by a computer software program, such that the voltage curve 406 is still similar to the voltage curve 402 or the voltage curve 404.

In sum, the test apparatus disclosed herein has an inventive configuration with a switchable power compensation circuit. The switchable power compensation circuit may be implemented with single power supply or two power supplies to meet various testing requirements. The test apparatus can have flexible power supply sources to meet various testing requirements.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A test apparatus configured to test a device under test, the test apparatus comprising:
a power supply configured to supply electric power to a power supply terminal of the device under test via a first route or a second route that are connected in parallel, wherein the first route comprises a first switch element configured to be controlled according to a first control signal; and
a power compensation circuit disposed on the second route, the power compensation circuit comprises a second switch element configured to be controlled according to a second control signal, the power compensation circuit is configured to generate a compensation pulse current when the first switch element is turned off and the second switch element is turned on.

2. The test apparatus of claim 1, wherein the power supply supplies electric power to the power supply terminal of the device under test via the first route when the first switch element is turned on and the second switch element is turned off.

3. The test apparatus of claim 1 further comprising a driver that is assigned to the second switch element.

4. The test apparatus of claim 1, wherein the device under test comprises an integrated circuit device that is packaged after an assembling process.

5. The test apparatus of claim 1, wherein the device under test comprises a memory integrated circuit device that is packaged after an assembling process.

6. The test apparatus of claim 5, wherein the memory integrated circuit device comprises double data rate synchronous dynamic random-access memory.

7. The test apparatus of claim 5, wherein the memory integrated circuit device comprises low power double data rate synchronous dynamic random-access memory.

8. The test apparatus of claim 1, wherein the power supply is configured to be modulated by a software application to compensate a power voltage drop when the power compensation circuit is malfunctioned.

9. A test apparatus configured to test a device under test, the test apparatus comprising:
a first power supply configured to supply electric power to a power supply terminal of the device under test via a first route;
a second power supply configured to supply electric power to the power supply terminal of the device under test via a second route; and
a power compensation circuit disposed on the second route, the power compensation circuit comprises a switch element configured to be controlled according to a control signal, the power compensation circuit is configured to generate a compensation pulse current when the switch element is turned on and the second power supply is turned on.

10. The test apparatus of claim 9, wherein the first power supply supplies electric power to the power supply terminal of the device under test via the first route when the switch element is turned off.

11. The test apparatus of claim 9, wherein the first power supply supplies electric power to the power supply terminal of the device under test via the first route when the second power supply is turned off.

12. The test apparatus of claim 9 further comprising a driver that is assigned to the switch element.

13. The test apparatus of claim 9, wherein the device under test comprises an integrated circuit device that is packaged after an assembling process.

14. The test apparatus of claim 9, wherein the device under test comprises a memory integrated circuit device that is packaged after an assembling process.

15. The test apparatus of claim 14, wherein the memory integrated circuit device comprises double data rate synchronous dynamic random-access memory.

16. The test apparatus of claim 14, wherein the memory integrated circuit device comprises low power double data rate synchronous dynamic random-access memory.

17. The test apparatus of claim 9, wherein the power compensation circuit is configured to compensate a power voltage drop.

18. The test apparatus of claim 9, wherein the first power supply is configured to be modulated by a software application to compensate a power voltage drop when the power compensation circuit is malfunctioned.
